(19) United States
(12) Patent Application Publication
(10) Pub. No.: US 2025/0040043 A1
(43) Pub. Date: Jan. 30, 2025

(54) SOLID COMPOSITION, CIRCUIT BOARD, AND METHOD FOR PRODUCING SOLID COMPOSITION

(71) Applicant: DAIKIN INDUSTRIES, LTD., Osaka (JP)

(72) Inventors: Kyouhei SAWAKI, Osaka (JP); Shingo OKUNO, Osaka (JP); Yuki UEDA, Osaka (JP); Mayuko TATEMICHI, Osaka (JP)

(73) Assignee: DAIKIN INDUSTRIES, LTD., Osaka (JP)

(21) Appl. No.: 18/906,241

(22) Filed: Oct. 4, 2024

Related U.S. Application Data
(63) Continuation of application No. PCT/JP2023/012319, filed on Mar. 27, 2023.

(30) Foreign Application Priority Data
Apr. 7, 2022 (JP) 2022-064020

(51) Int. Cl. H05K 1/03; C08J 3/20; C08J 5/18; C08K 9/06

(52) U.S. Cl. CPC H05K 1/0373; C08J 3/201; C08J 5/18; C08K 9/06; C08J 2327/18; H05K 2201/015

(57) ABSTRACT

Provided are a solid composition having a low linear expansion coefficient and good moldability, a circuit board, and a method for producing the solid composition. The solid composition contains: a perfluorinated fluororesin; and an anisotropic filler surface-treated with a silane coupling agent.

### CROSS-REFERENCE TO RELATED APPLICATIONS

This application is a Rule 53(b) Continuation of International Application No. PCT/JP2023/012319 filed Mar. 27, 2023, which claims priority based on Japanese Patent Application No. 2022-064020 filed Apr. 7, 2022, the respective disclosures of which are incorporated herein by reference in their entirety.

### TECHNICAL FIELD

The disclosure relates to solid compositions, circuit boards, and methods for producing the solid compositions.

### BACKGROUND ART

Speeding up of communication generates a demand for low dielectric, low loss materials for circuit boards to be used in devices such as electrical devices, electronic devices, and communication devices. Fluororesins are examined as these materials. One of the challenges in using fluororesins is to reduce their linear expansion coefficient.

Patent Literature 1 discloses a resin composition for dielectrics, containing an inorganic substance dispersed in a thermoplastic resin and/or a thermosetting resin.

Patent Literature 2 discloses a dispersion containing tetrafluoroethylene-based polymer powder, an anisotropic filler, and a liquid dispersion medium.

### CITATION LIST

### Patent Literature

Patent Literature 1: JP 2015-40296 A
Patent Literature 2: WO 2021/112164

### SUMMARY

The disclosure (1) relates to a solid composition (hereinafter, also referred to as “the solid composition of the disclosure”) containing:
a perfluorinated fluororesin; and
an anisotropic filler surface-treated with a silane coupling agent.

### Advantageous Effects

The disclosure can provide a solid composition having a low linear expansion coefficient and good moldability, a circuit board, and a method for producing the solid composition.

### DESCRIPTION OF EMBODIMENTS

The “organic group” herein means a group containing at least one carbon atom or a group formed by removing one hydrogen atom from an organic compound.

Examples of this “organic group” include
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent,
a heteroaryl group optionally containing at least one substituent,
a cyano group,
a formyl group,
RaO—,
RaCO—,
RaSO₂—,
RaCOO—,
RaNRaCO—,
RaCONRa-,
RaOCO—,
RaOSO₂—, and
RaNRbSO₂—,
wherein
the Ra groups are each independently
an alkyl group optionally containing at least one substituent,
an alkenyl group optionally containing at least one substituent,
an alkynyl group optionally containing at least one substituent,
a cycloalkyl group optionally containing at least one substituent,
a cycloalkenyl group optionally containing at least one substituent,
a cycloalkadienyl group optionally containing at least one substituent,
an aryl group optionally containing at least one substituent,
an aralkyl group optionally containing at least one substituent,
a non-aromatic heterocyclic group optionally containing at least one substituent, or
a heteroaryl group optionally containing at least one substituent, and
the Rb groups are each independently H or an alkyl group optionally containing at least one substituent.

The organic group is preferably an alkyl group optionally containing at least one substituent.

The disclosure will be specifically described hereinbelow.

The solid composition of the disclosure contains a perfluorinated fluororesin and an anisotropic filler surface-treated with a silane coupling agent.

The solid composition of the disclosure that contains the anisotropic filler has a low linear expansion coefficient and good moldability despite the perfluorinated fluororesin contained therein.

Moreover, upon forming pellets from the solid composition of the disclosure, the anisotropic filler contained in the solid composition reduces voids inside the pellets. Thus, films or sheets formed from the pellets have good mechanical properties.

Further, the contained anisotropic filler can improve electric properties.

As described in Patent Literature 1, usually, strong stress is necessary to melt-knead an anisotropic filler and a fluororesin. This may impair the properties (e.g., the effect of improving electric properties) of the anisotropic filler. In contrast, since the surface of the above-described anisotropic filler is treated with a silane coupling agent, the anisotropic filler can maintain its properties even when it is melt-kneaded with a fluororesin. The melt-kneading allows the anisotropic filler to be well dispersed in the fluororesin, whereby better properties such as electric properties can be obtained.

The solid composition of the disclosure that is solid is advantageous in that it can be produced with a fewer steps than the dispersion in Patent Literature 2 and can be easily formed into a thick film.

Additionally, since a perfluorinated fluororesin is used in the solid composition of the disclosure, the solid composition can obtain better electric properties, compared to the use of other fluororesins such as an ethylene/tetrafluoroethylene (ETFE) copolymer.

The perfluorinated fluororesin is a copolymer containing as a main component a fluorine-containing monomer such as a perfluoromonomer, and is a fluororesin containing a very small number of hydrogen atoms bonded to a carbon atom in a repeating unit of the main chain. Portions other than the repeating unit of the main chain, such as an end structure, may contain a hydrogen atom bonded to a carbon atom. A monomer other than the fluorine-containing monomer may be copolymerized as long as the resin contains the fluorine-containing monomer in an amount of 90 mol % or more. The amount of the fluorine-containing monomer is preferably 95 mol % or more, more preferably 99 mol % or more, and may be 100 mol %.

The perfluorinated fluororesin used may be a polymer of tetrafluoroethylene (TFE), which is a perfluoromonomer, or a copolymer of TFE and a copolymerizable monomer copolymerizable with TFE, for example.

The “perfluoromonomer” herein means a monomer in which all hydrogen atoms bonded to any carbon atom are replaced by fluorine atoms.

The copolymerizable monomer may be any monomer copolymerizable with TFE and free from a hydrogen atom bonded to a carbon atom of the main chain. Examples thereof include fluorine-containing monomers such as hexafluoropropylene (HFP) and those to be described later, including a fluoroalkyl vinyl ether, a fluoroalkyl ethylene, a fluoromonomer represented by the formula (100) CH₂═CFRf¹⁰¹ (wherein Rf¹⁰¹ is a C1-C12 linear or branched fluoroalkyl group), and a fluoroalkyl allyl ether. Examples of the monomer other than the fluorine-containing monomers include itaconic anhydride, citraconic anhydride, 5-norbornene-2,3-dicarboxylic acid anhydride, and maleic anhydride. One of these copolymerizable monomers may be used alone or two or more thereof may be used in combination.

The fluoroalkyl vinyl ether preferably includes at least one selected from the group consisting of:
a fluoromonomer represented by the formula (110):

CF₂═CF—ORf¹¹¹

wherein Rf¹¹¹ is a perfluoro organic group;
a fluoromonomer represented by the formula (120):

CF₂═CF—OCH₂—Rf¹²¹

wherein Rf¹²¹ is a C1-C5 perfluoroalkyl group;
a fluoromonomer represented by the formula (130):

CF₂═CFOCF₂ORf¹³¹

wherein Rf¹³¹ is a C1-C6 linear or branched perfluoroalkyl group, a C5-C6 cyclic perfluoroalkyl group, or a C2-C6 linear or branched perfluorooxyalkyl group containing one to three oxygen atoms;
a fluoromonomer represented by the formula (140):

CF₂═CFO(CF₂CF(Y¹⁴¹)O)ₘ(CF₂)ₙF

wherein Y¹⁴¹ is a fluorine atom or a trifluoromethyl group; m is an integer of 1 to 4; and n is an integer of 1 to 4; and
a fluoromonomer represented by the formula (150):

CF₂═CF—O—(CF₂CFY¹⁵¹—O)ₙ—(CFY¹⁵²)ₘ-A¹⁵¹

wherein Y¹⁵¹ is a fluorine atom, a chlorine atom, a —SO₂F group, or a perfluoroalkyl group, where the perfluoroalkyl group optionally contains ether oxygen and a —SO₂F group; n is an integer of 0 to 3; n Y¹⁵¹s are the same as or different from each other; Y¹⁵² is a fluorine atom, a chlorine atom, or a —SO₂F group; m is an integer of 1 to 5; m Y¹⁵²s are the same as or different from each other; and A¹⁵¹ is —SO₂X¹⁵¹, —COZ¹⁵¹, or —POZ⁵²Z¹⁵³, where X¹⁵¹ is F, Cl, Br, I, —OR¹⁵¹, or —NR¹⁵²R¹⁵³, and Z¹⁵¹, Z¹⁵², and Z¹⁵³ are the same as or different from each other and are each —NR¹⁵⁴R¹⁵⁵ or —OR¹⁵⁶, and where R¹⁵¹, R¹⁵², R¹⁵³, R¹⁵⁴, R¹⁵⁵, and R¹⁵⁶ are the same as or different from each other and are each H, ammonium, an alkali metal, or an alkyl group, aryl group, or sulfonyl-containing group optionally containing a fluorine atom.

The “perfluoro organic group” herein means an organic group in which all hydrogen atoms bonded to any carbon atom are replaced by fluorine atoms. The perfluoro organic group may have ether oxygen.

An example of the fluoromonomer represented by the formula (110) may be a fluoromonomer in which Rf¹¹¹ is a C1-C10 perfluoroalkyl group. The carbon number of the perfluoroalkyl group is preferably 1 to 5.

Examples of the perfluoro organic group in the formula (110) include a perfluoromethyl group, a perfluoroethyl group, a perfluoropropyl group, a perfluorobutyl group, a perfluoropentyl group, and a perfluorohexyl group.

Examples of the fluoromonomer represented by the formula (110) also include:
a monomer represented by the formula (110) in which Rf¹¹¹ is a C4-C9 perfluoro(alkoxyalkyl)group;
a monomer in which Rf¹¹¹ is a group represented by the following formula:

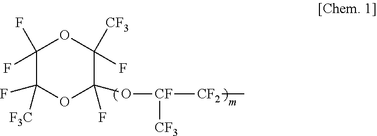

wherein m is 0 or an integer of 1 to 4; and
a monomer in which Rf¹¹¹ is a group represented by the following formula:

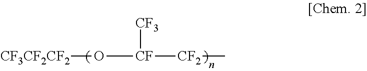

wherein n is an integer of 1 to 4.

In particular, the fluoromonomer represented by the formula (110) is preferably a perfluoro(alkyl vinyl ether) (PAVE), more preferably a fluoromonomer represented by the formula (160):

CF₂═CF—ORf¹⁶¹

wherein Rf¹⁶¹ is a C1-C10 perfluoroalkyl group. Rf¹⁶¹ is preferably a C1-C5 perfluoroalkyl group.

The fluoroalkyl vinyl ether preferably includes at least one selected from the group consisting of fluoromonomers represented by any of the formulas (160), (130), and (140).

The fluoromonomer (PAVE) represented by the formula (160) preferably includes at least one selected from the group consisting of perfluoro(methyl vinyl ether) (PMVE), perfluoro(ethyl vinyl ether) (PEVE), and perfluoro(propyl vinyl ether) (PPVE), more preferably includes at least one selected from the group consisting of perfluoro(methyl vinyl ether) and perfluoro(propyl vinyl ether).

The fluoromonomer represented by the formula (130) preferably includes at least one selected from the group consisting of CF₂═CFOCF₂OCF₃, CF₂═CFOCF₂OCF₂CF₃, and CF₂═CFOCF₂OCF₂CF₂OCF₃.

The fluoromonomer represented by the formula (140) preferably includes at least one selected from the group consisting of CF₂═CFOCF₂CF(CF₃)O(CF₂)₃F, CF₂═CFO(CF₂CF(CF₃)O)₂(CF₂)₃F, and CF₂═CFO(CF₂CF(CF₃)O)₂(CF₂)₂F.

The fluoromonomer represented by the formula (150) preferably includes at least one selected from the group consisting of CF₂═CFOCF₂CF₂SO₂F, CF₂═CFOCF₂CF(CF₃)OCF₂CF₂SO₂F, CF₂═CFOCF₂CF(CF₂CF₂SO₂F)OCF₂CF₂SO₂F, and CF₂═CFOCF₂CF(SO₂F)₂.

The fluoromonomer represented by the formula (100) is preferably a fluoromonomer in which Rf¹⁰¹ is a linear fluoroalkyl group, more preferably a fluoromonomer in which Rf¹⁰¹ is a linear perfluoroalkyl group. Rf¹⁰¹ preferably has a carbon number of 1 to 6. Examples of the fluoromonomer represented by the formula (100) include CH₂═CFCF₃, CH₂═CFCF₂CF₃, CH₂═CFCF₂CF₂CF₃, CH₂═CFCF₂CF₂CF₂H, CH₂═CFCF₂CF₂CF₂CF₃, CHF═CHCF₃ (E configuration), and CHF═CHCF₃ (Z configuration). Preferred among these is 2,3,3,3-tetrafluoropropylene represented by CH₂═CFCF₃.

The fluoroalkylethylene is preferably a fluoroalkylethylene represented by the formula (170):

CH₂═CH—(CF₂)ₙ—X¹⁷¹

(wherein X¹⁷¹ is H or F; and n is an integer of 3 to 10); and more preferably includes at least one selected from the group consisting of CH₂═CH—C₄F₉ and CH₂═CH—C₆F₁₃.

An example of the fluoroalkyl allyl ether may be a fluoromonomer represented by the formula (171):

CF₂═CF—CF₂—ORf¹¹¹

wherein Rf¹¹¹ is a perfluoro organic group.

Rf¹¹¹ in the formula (170) is defined as described for Rf¹¹¹ in the formula (110). Rf¹¹¹ is preferably a C1-C10 perfluoroalkyl group or a C1-C10 perfluoroalkoxyalkyl group. The fluoroalkyl allyl ether represented by the formula (170) preferably includes at least one selected from the group consisting of CF₂═CF—CF₂—O—CF₃, CF₂═CF—CF₂—O—C₂F₅, CF₂═CF—CF₂—O—C₃F₇, and CF₂═CF—CF₂—O—C₄F₉, more preferably includes at least one selected from the group consisting of CF₂═CF—CF₂—O—C₂F₅, CF₂═CF—CF₂—O—C₃F₇, and CF₂═CF—CF₂—O—C₄F₉, and is still more preferably CF₂═CF—CF₂—O—CF₂CF₂CF₃.

To achieve less deformation and a lower linear expansion coefficient of the solid composition, the copolymerizable monomer is preferably a monomer containing a perfluorovinyl group, more preferably includes at least one selected from the group consisting of a perfluoro(alkyl vinyl ether) (PAVE), hexafluoropropylene (HFP), and perfluoroallyl ether, still more preferably includes at least one selected from the group consisting of PAVE and HFP. To reduce deformation of the solid composition during soldering, PAVE is particularly preferred.

The perfluorinated fluororesin preferably contains a unit of the copolymerizable monomer in a total amount of 0.1% by mass or more, more preferably 1.0% by mass or more, still more preferably 1.1% by mass or more of all monomer units. The total amount of the copolymerizable monomer unit is also preferably 30% by mass or less, more preferably 20% by mass or less, still more preferably 15% by mass or less of all monomer units.

The amount of the copolymerizable monomer unit is determined by ¹⁹F-NMR.

To achieve less deformation and a lower linear expansion coefficient of the solid composition, the perfluorinated fluororesin preferably includes at least one selected from the group consisting of polytetrafluoroethylene (PTFE), a tetrafluoroethylene (TFE)/perfluoro(alkyl vinyl)ether (PAVE) copolymer (PFA), and a tetrafluoroethylene (TFE)/hexafluoropropylene (HFP) copolymer (FEP), more preferably at least one selected from the group consisting of PFA and FEP, and is still more preferably PFA.

In the case where the perfluorinated fluororesin is PFA containing a TFE unit and a PAVE unit, the PAVE unit is preferably contained in an amount of 0.1 to 12% by mass of all polymerized units. The amount of the PAVE unit is more preferably 0.3% by mass or more, still more preferably 0.7% by mass or more, further preferably 1.0% by mass or more, particularly preferably 1.1% by mass or more, while it is more preferably 8.0% by mass or less, still more preferably 6.5% by mass or less, particularly preferably 6.0% by mass or less of all polymerized units.

The amount of the PAVE unit is determined by ¹⁹F-NMR.

In the case where the perfluorinated fluororesin is FEP containing a TFE unit and a HFP unit, the TFE unit and the HFP unit preferably have a mass ratio (TFE/HFP) of (70 to 99)/(1 to 30) (% by mass). The mass ratio (TFE/HFP) is more preferably (85 to 95)/(5 to 15) (% by mass).

The FEP contains the HFP unit in an amount of 1% by mass or more, preferably 1.1% by mass or more of all monomer units.

The FEP preferably contains a perfluoro(alkyl vinyl ether) (PAVE) unit as well as the TFE unit and the HFP unit.

Examples of the PAVE unit contained in the FEP include the same as the PAVE units to form the aforementioned PFA. Preferred among these is PPVE.

The aforementioned PFA contains no HFP unit and is therefore different from the FEP containing a PAVE unit in this respect.

In the case where the FEP contains a TFE unit, a HFP unit, and a PAVE unit, they preferably have a mass ratio (TFE/HFP/PAVE) of (70 to 99.8)/(0.1 to 25)/(0.1 to 25) (% by mass). The FEP having a mass ratio within this range can have excellent heat resistance and excellent chemical resistance.

The mass ratio (TFE/HFP/PAVE) is more preferably (75 to 98)/(1.0 to 15)/(1.0 to 10) (% by mass).

The FEP contains the HFP unit and the PAVE unit in a total amount of 1% by mass or more, preferably 1.1% by mass or more of all monomer units.

The FEP containing a TFE unit, a HFP unit, and a PAVE unit preferably contains the HFP unit in an amount of 25% by mass or less of all monomer units.

The HFP unit contained in an amount within this range can lead to a solid composition having excellent heat resistance.

The amount of the HFP unit is more preferably 20% by mass or less, still more preferably 18% by mass or less, particularly preferably 15% by mass or less. The amount of the HFP unit is also preferably 0.1% by mass or more, more preferably 1% by mass or more, particularly preferably 2% by mass or more.

The amount of the HFP unit can be determined by ¹⁹F-NMR.

The amount of the PAVE unit is more preferably 20% by mass or less, still more preferably 10% by mass or less, particularly preferably 3% by mass or less. The amount of the PAVE unit is also preferably 0.1% by mass or more, more preferably 1% by mass or more. The amount of the PAVE unit can be determined by ¹⁹F-NMR.

The FEP may further contain a different ethylenic monomer (α) unit.

The different ethylenic monomer (α) unit may be any monomer unit copolymerizable with TFE, HFP, and PAVE. Examples thereof include fluorine-containing ethylenic monomers such as vinyl fluoride (VF), vinylidene fluoride (VdF), and chlorotrifluoroethylene (CTFE), as well as non-fluorinated ethylenic monomers such as ethylene, propylene, and alkyl vinyl ethers.

In the case where the FEP contains a TFE unit, a HFP unit, a PAVE unit, and a different ethylenic monomer (ca) unit, they preferably have a mass ratio (TFE/HFP/PAVE/different ethylenic monomer (α)) of (70 to 98)/(0.1 to 25)/(0.1 to 25)/(0.1 to 10) (% by mass).

The FEP contains the monomer units excluding the TFE unit in a total amount of 1% by mass or more, preferably 1.1% by mass or more of all monomer units.

The perfluorinated fluororesin also preferably includes the PFA and the FEP. In other words, the PFA and the FEP may be used as a mixture thereof. The PFA and the FEP preferably have a mass ratio (PFA/FEP) of 90/10 to 30/70, more preferably 90/10 to 50/50.

The PFA and the FEP each may be produced, for example, by a conventionally known method in which monomers to serve as the structural units and additives such as a polymerization initiator are mixed as appropriate, followed by emulsion polymerization or suspension polymerization.

The perfluorinated fluororesin contains preferably less than 700, more preferably less than 300, still more preferably less than 100, particularly preferably less than 50 unstable end groups per 1×10⁶ carbon atoms. The lower limit is not limited. With the number of unstable end groups being within this range, better electric properties can be obtained.

In view of electric properties (especially dissipation factor), the unstable end groups preferably include at least one selected from the group consisting of —CF₂H, —COF, —COOH, —COOCH₃, —CONH₂, and —CH₂OH present at a main chain end of the perfluorinated fluororesin. They may be associated with water.

The perfluorinated fluororesin contains preferably less than 600, more preferably less than 200, still more preferably less than 100, particularly preferably less than 30 —CF₂H ends per 1×10⁶ carbon atoms. The lower limit is not limited. With the number of —CF₂H ends being within this range, better electric properties (especially dissipation factor) can be obtained.

The number of unstable end groups can be reduced by fluorination treatment on the perfluorinated fluororesin, for example.

The fluorination treatment can be performed by a known method, such as contact between a fluororesin without fluorination treatment and a fluorine-containing compound.

Examples of the fluorine-containing compound include fluorine radical sources that generate fluorine radicals under fluorination treatment conditions, such as F₂ gas, CoF₃, AgF₂, UF₆, OF₂, N₂F₂, CF₃OF, and halogen fluorides, e.g., IF₅ and ClF₃.

The number of unstable end groups can be determined by infrared spectroscopy. Specifically, first, a film-shaped sample with a thickness of 0.25 to 0.3 mm is prepared from the perfluorinated fluororesin. This sample is analyzed by Fourier transform infrared spectroscopy to provide an infrared absorption spectrum of the copolymer, and a difference spectrum is obtained between the resulting spectrum and a base spectrum without unstable end groups owing to complete fluorination treatment. Based on the absorption peaks of specific unstable end groups appearing in this difference spectrum, the number N of unstable end groups per 10⁶ carbon atoms in the copolymer is calculated based on the following formula (A).

$$N = I \times K / t \qquad ( A )$$

I: Absorbance
K: Correction coefficient
t: Thickness of film (sample) (mm)

The sample is cut out of a pellet or a sheet formed from the perfluorinated fluororesin.

The perfluorinated fluororesin preferably has a melting point of 240° C. to 340° C. This enables easy melt kneading.

The melting point of the perfluorinated fluororesin is more preferably 318° C. or lower, still more preferably 315° C. or lower, while it is more preferably 245° C. or higher, still more preferably 250° C. or higher.

The melting point of the perfluorinated fluororesin is the temperature corresponding to the maximum value on a heat-of-fusion curve with a temperature-increasing rate of 10° C./min using a differential scanning calorimeter (DSC).

The perfluorinated fluororesin preferably has a melt flow rate (MFR) at 372° C. of 0.1 to 100 g/10 min. This enables easy melt kneading.

The MFR is more preferably 0.5 g/10 min or higher, still more preferably 1.5 g/10 min or higher, while it is more preferably 80 g/10 min or lower, still more preferably 40 g/10 min or lower.

The MFR is a value obtained as the mass (g/10 min) of a polymer flowing out of a nozzle (inner diameter: 2 mm, length: 8 mm) per 10 minutes at a temperature of 372° C. and a load of 5 kg using a melt indexer (available from Yasuda Seiki Seisakusho Ltd.) in conformity with ASTM D1238.

The perfluorinated fluororesin may have any relative permittivity and any dissipation factor. The relative permittivity at 25° C. and a frequency of 10 GHz is preferably 4.5 or lower, more preferably 4.0 or lower, still more preferably 3.5 or lower, particularly preferably 2.5 or lower. The dissipation factor is 0.01 or lower, preferably 0.008 or lower, more preferably 0.005 or lower. The lower limits may be, but are not limited to, 1.0 or higher for the relative permittivity and 0.0001 or higher for the dissipation factor, for example.

The amount of the perfluorinated fluororesin relative to the solid composition is preferably 40 to 90% by mass. The amount of the perfluorinated fluororesin is more preferably 50% by mass or more, still more preferably 60% by mass or more, particularly preferably 70% by mass or more, while it is more preferably 85% by mass or less, more preferably 80% by mass or less.

The anisotropic filler includes anisotropic (having different diameters in different directions) particles, such as carbon, mica, clay, and talc. Nitrides such as boron nitride and silicon nitride are also usable. To obtain better moldability, talc and boron nitride are preferred, and talc is more preferred among these.

One of the anisotropic fillers may be used or two or more thereof may be used.

To obtain good dispersibility, the anisotropic filler has a Mohs hardness of preferably 4 or lower. The anisotropic filler has a Mohs hardness of more preferably 3 or lower and preferably 1 or higher.

The Mohs hardness refers to the original Mohs hardness on a scale of 1 to 10 and can be measured with a Mohs hardness meter.

The anisotropic filler preferably has an average particle size of 0.1 to 50 μm. The average particle size is more preferably 1 μm or more, still more preferably 3 μm or more, particularly preferably 5 μm or more, while it is more preferably 30 μm or less, still more preferably 20 μm or less, particularly preferably 15 μm or less.

The average particle size is a value determined by the laser diffraction scattering method.

The anisotropic filler preferably has an aspect ratio of 1 to 5000. The lower limit of the aspect ratio is more preferably 10, still more preferably 20. The upper limit of the aspect ratio is more preferably 1000, still more preferably 200.

The aspect ratio is a value calculated by dividing the average particle size of the anisotropic filler by the average minor axis (average length in the shorter direction).

The anisotropic filler may be in any form. Examples of the form include a flaky form, a plate form, a needle form, a granular form, a spherical form, a columnar form, a cone shape, a pyramid shape, a frustum shape, and a hollow form.

The anisotropic filler is surface-treated with a silane coupling agent. The surface treatment may be performed by any method including a usual method.

One of the silane coupling agents may be used or two or more thereof may be used.

To enhance the affinity with resins, the silane coupling agent preferably contains at least one functional group selected from the group consisting of a fluorine-containing group, an amino group, a vinyl group, and an epoxy group, more preferably at least one functional group selected from the group consisting of a fluorine-containing group, an amino group, and a vinyl group, still more preferably a fluorine-containing group or an amino group.

The amount of the anisotropic filler relative to the solid composition is preferably 10 to 60% by mass. The amount of the anisotropic filler is more preferably 15% by mass or more, still more preferably 20% by mass or more, while it is more preferably 50% by mass or less, still more preferably 45% by mass or less.

The solid composition may further contain a different component as appropriate. Examples of the different component include additives such as a filler, a cross-linker, an antistatic agent, a heat-resistance stabilizer, a foaming agent, a foam nucleating agent, an antioxidant, a surfactant, a photopolymerization initiator, an anti-wear agent, a surface modifier, a resin other than the modified fluororesin, and a liquid crystal polymer.

The different component preferably includes an inorganic filler other than the anisotropic filler. The presence of such an inorganic filler can give effects of improving the strength and of reducing the linear expansion coefficient, for example.

Specific examples of the inorganic filler include zinc oxide and inorganic compounds other than zinc oxide such as silica (e.g., more specifically, crystalline silica, fused silica, spherical fused silica), titanium oxide, zirconium oxide, tin oxide, silicon nitride, silicon carbide, boron nitride, calcium carbonate, calcium silicate, potassium titanate, aluminum nitride, indium oxide, alumina, antimony oxide, cerium oxide, magnesium oxide, iron oxide, and tin-doped indium oxide (ITO).

Examples also include minerals such as montmorillonite, talc, mica, boehmite, kaolin, smectite, xonotlite, vermiculite, and sericite. Examples of other inorganic fillers include carbon compounds such as carbon black, acetylene black, ketjen black, and carbon nanotube; metal hydroxides such as aluminum hydroxide and magnesium hydroxide; and glasses such as glass beads, glass flakes, and glass balloons.

One of the inorganic fillers may be used or two or more thereof may be used.

The inorganic filler in the form of powder may be used as it is or may be dispersed in a resin before use.

The inorganic filler preferably has ultraviolet absorbency. The phrase “has ultraviolet absorbency” means that the absorbance of light at a wavelength of 355 nm is 0.1 or more.

The absorbance of light is a value of powder of the inorganic filler packed to have a thickness of 100 μm and is measured using a UV-VIS-NIR spectrophotometer (e.g., “V-770” available from Jasco Corp.) in the reflection geometry.

Examples of the inorganic filler having ultraviolet absorbency include zinc oxide and titanium oxide. Zinc oxide is preferred.

The inorganic filler may be in any form. Examples of the form include those described for the anisotropic filler.

The amount of the inorganic filler, if present, in the solid composition of the disclosure relative to the solid composition is preferably 0.01 to 5.0% by mass. The amount of the inorganic filler is more preferably 0.1% by mass or more, still more preferably 0.3% by mass or more, while it is more preferably 4.0% by mass or less, still more preferably 3.0% by mass or less.

The inorganic filler preferably has an average particle size of 0.01 to 20 μm. The inorganic filler having an average particle size within this range is less likely to aggregate and can give good surface roughness. The lower limit of the average particle size is more preferably 0.02 μm, still more preferably 0.03 μm. The upper limit of the average particle size is more preferably 5 μm, still more preferably 2 μm.

The average particle size is a value determined by the laser diffraction scattering method.

The inorganic filler may be surface-treated, and may be, for example, surface-treated with a silicone compound. This surface treatment with a silicone compound can reduce the permittivity of the inorganic filler.

The silicone compound used may be, but is not limited to, a conventionally known silicone compound. For example, the silicone compound preferably includes at least one selected from the group consisting of a silane coupling agent and an organosilazane.

The amount of the silicone compound used for the surface treatment, which is expressed by the amount of the surface-treating agent reacted with the surface of the inorganic filler, is preferably 0.1 to 10 molecules, more preferably 0.3 to 7 molecules per unit surface area (nm²).

The solid composition of the disclosure preferably has 30 or less voids having a width of 30 μm or greater per 1 mm² area in image analysis by laser microscopy. The number of voids is more preferably 25 or less, still more preferably 20 or less, and may be 0. With the number of voids being within this range, better moldability (especially sheet moldability, stability in taking up a strand) can be obtained.

The image analysis by laser microscopy is performed on a cross section of a pellet formed from the solid composition of the disclosure.

The solid composition of the disclosure preferably has a linear expansion coefficient at 20° C. to 200° C. of 160 ppm/° C. or lower, more preferably 120 ppm/° C. or lower. The lower limit is not limited and may be, for example, 100 ppm/° C.

The solid composition has a reduction percentage in linear expansion coefficient at 20° C. to 200° C. of preferably 25% or higher, more preferably 40% or higher, still more preferably 50% or higher relative to the linear expansion coefficient at 20° C. to 200° C. of the perfluorinated fluororesin. The upper limit is not limited and may be, for example, 60%.

The solid composition of the disclosure has a relative permittivity at 25° C. and 10 GHz of preferably 5.0 or lower, more preferably 4.0 or lower, still more preferably 3.5 or lower. The lower limit thereof may be, but is not limited to, 1.0, for example. The solid composition having a relative permittivity within this range can suitably be used in circuit boards.

The solid composition of the disclosure has a dissipation factor at 25° C. and 10 GHz of preferably 0.003 or lower, more preferably 0.002 or lower, still more preferably 0.0015 or lower. The lower limit thereof may be, but is not limited to, 0.0001 or higher, for example. The solid composition having a dissipation factor within this range can suitably be used in circuit boards.

Non-limiting examples of the form of the solid composition of the disclosure include pellet, film, and sheet. The solid composition for use in a circuit board is preferably in the form of film or sheet. Pellets of the solid composition are usable as a molding material.

The solid composition of the disclosure can suitably be produced by a production method in which the perfluorinated fluororesin and the anisotropic filler are melt-kneaded to provide the solid composition. The disclosure also provides this production method.

The solid composition of the disclosure may be produced by a method other than the above production method, such as injection molding, blow molding, inflation molding, or vacuum or pressure forming. In the case where the materials are dispersed or dissolved in a solvent, the solid composition may be produced by paste extrusion or casting.

Any device may be used for the melt-kneading, such as a twin-screw extruder, a single-screw extruder, a multi-screw extruder, or a tandem extruder.

The duration of the melt-kneading is preferably 1 to 1800 seconds, more preferably 60 to 1200 seconds. Too long melt-kneading may impair the fluororesin, while too short melt-kneading may cause insufficient dispersion of the zinc oxide.

The temperature of the melt-kneading is not lower than the melting points of the perfluorinated fluororesin and the anisotropic filler, and is preferably 240° C. to 450° C., more preferably 260° C. to 400° C.

The inventors have found that the solid composition of the disclosure containing a perfluorinated fluororesin and an anisotropic filler has good dispersibility as well as a low liner expansion coefficient and excellent moldability. These characteristics are suitable for materials for circuit boards.

In other words, the solid composition of the disclosure can suitably be used as an insulating material (especially a low dielectric material) or a thermally conductive material of a circuit board.

The “low dielectric material” as used herein means a material having a relative permittivity at 25° C. and 10 GHz of 5.0 or lower and a dissipation factor at 25° C. and 10 GHz of 0.003 or lower; more preferably a material having a relative permittivity at 25° C. and 10 GHz of 4.0 or lower and a dissipation factor at 25° C. and 10 GHz of 0.002 or lower; still more preferably a material having a relative permittivity at 25° C. and 10 GHz of 3.5 or lower and a dissipation factor at 25° C. and 10 GHz of 0.0012 or lower.

The circuit board of the disclosure includes the aforementioned solid composition of the disclosure and a conductive layer.

The conductive layer used preferably contains metal.

Examples of the metal include copper, stainless steel, aluminum, iron, silver, gold, and ruthenium. Alloys of any of these may also be used. Preferred is copper.

The copper used may be rolled copper or electrolytic copper.

The metal preferably has a surface having a surface roughness Rz of 2.0 μm or lower on a side facing the solid composition. This can lead to a good transmission loss when the solid composition and the metal are joined together.

The surface roughness Rz is more preferably 1.8 μm or lower, still more preferably 1.5 μm or lower, while it is more preferably 0.3 μm or higher, still more preferably 0.5 μm or higher.

The surface roughness Rz is a value calculated in accordance with the method in JIS C 6515-1998 (maximum height roughness).

The conductive layer may have a thickness of 2 to 200 μm, preferably 5 to 50 μm, for example.

The conductive layer may be provided on one side of a layer containing the solid composition of the disclosure or may be provided on both sides thereof.

The thickness of the layer containing the solid composition of the disclosure may be, for example, 1 μm to 1 mm, preferably 20 μm or more, more preferably 30 μm or more, still more preferably 50 μm or more, while it is preferably 800 μm or less, more preferably 600 μm or less.

In the case of forming a film from the dispersion in Patent Literature 2, usually a film having a thickness of 50 μm or more is difficult to form. In the case of forming a film from the solid composition of the disclosure, a film having a thickness of 50 μm or more can easily be formed.

The circuit board of the disclosure may further include a resin other than the perfluorinated fluororesin stacked on the solid composition of the disclosure and the conductive layer.

The resin other than the perfluorinated fluororesin suitably used may be a thermosetting resin.

The thermosetting resin preferably includes at least one selected from the group consisting of polyimide, modified polyimide, epoxy resin, and thermosetting modified polyphenylene ether, and is more preferably epoxy resin, modified polyimide, or thermosetting modified polyphenylene ether, still more preferably epoxy resin or thermosetting modified polyphenylene ether.

The resin other than the perfluorinated fluororesin may be a resin other than the thermosetting resin.

The resin other than the thermosetting resin preferably includes at least one selected from the group consisting of a liquid crystal polymer, polyphenylene ether, thermoplastic modified polyphenylene ether, a cycloolefin polymer, a cycloolefin copolymer, polystyrene, and syndiotactic polystyrene.

The resin other than the perfluorinated fluororesin has a thickness of preferably 5 μm or greater, more preferably 10 μm or greater, while preferably 2000 μm or smaller, more preferably 1500 μm or smaller.

The resin other than the perfluorinated fluororesin is preferably in the form of sheet having a substantially constant thickness. In the case where the perfluorinated fluororesin includes portions having different thicknesses, the thickness refers to the average of the thicknesses measured at the points defined by dividing the perfluorinated fluororesin into 10 equal parts in the longitudinal direction.

The circuit board of the disclosure has a thickness of preferably 20 μm or greater, more preferably 30 μm or greater, while preferably 5000 μm or smaller, more preferably 3000 μm or smaller.

The circuit board of the disclosure is preferably in the form of sheet having a substantially constant thickness. In the case where the board includes portions having different thicknesses, the thickness refers to the average of the thicknesses measured at the points defined by dividing the board into 10 equal parts in the longitudinal direction.

The circuit board of the disclosure is suitably used as a printed circuit board, a multilayer circuit board (multilayer board), or a high frequency board.

The high frequency circuit board is a circuit board that is operable in a high frequency band. The high frequency band may be a band of 1 GHz or higher, preferably a band of 3 GHz or higher, more preferably a band of 5 GHz or higher. The upper limit may be, but is not limited to, a band of 100 GHz or lower.

The circuit board of the disclosure is preferably in the form of sheet. The circuit board of the disclosure preferably has a thickness of 10 to 3500 μm, more preferably 20 to 3000 μm.

Although some embodiments are described above, it will be understood that various changes in the embodiments and the details can be made without departing from the gist and scope of the Claims.

The disclosure (1) relates to a solid composition (hereinafter, also referred to as “the solid composition of the disclosure”) containing:
a perfluorinated fluororesin; and
an anisotropic filler surface-treated with a silane coupling agent.

The disclosure (2) relates to the solid composition according to the disclosure (1),
wherein the anisotropic filler includes at least one of talc or boron nitride.

The disclosure (3) relates to the solid composition according to the disclosure (1) or (2),
wherein the anisotropic filler has a Mohs hardness of 4 or lower.

The disclosure (4) relates to the solid composition according to any one of the disclosures (1) to (3),
wherein the silane coupling agent contains at least one selected from the group consisting of a fluorine-containing group, an amino group, a vinyl group, and an epoxy group.

The disclosure (5) relates to the solid composition according to any one of the disclosures (1) to (4),
wherein the perfluorinated fluororesin contains less than 50 unstable end groups per 1×10⁶ carbon atoms,
the unstable end groups include at least one selected from the group consisting of —CF₂H, —COF, —COOH, —COOCH₃, —CONH₂, and —CH₂OH present at a main chain end of the perfluorinated fluororesin.

The disclosure (6) relates to the solid composition according to any one of the disclosures (1) to (5),
wherein the perfluorinated fluororesin includes at least one selected from the group consisting of polytetrafluoroethylene, a tetrafluoroethylene/perfluoro(alkyl vinyl ether) copolymer, and a tetrafluoroethylene/hexafluoropropylene copolymer.

The disclosure (7) relates to the solid composition according to any one of the disclosures (1) to (6),
wherein the solid composition has 30 or less voids having a width of 30 μm or greater per 1 mm² area in image analysis by laser microscopy.

The disclosure (8) relates to the solid composition according to any one of the disclosures (1) to (7),
wherein the solid composition has a reduction percentage in linear expansion coefficient at 20° C. to 200° C. of 25% or higher relative to a linear expansion coefficient at 20° C. to 200° C. of the perfluorinated fluororesin.

The disclosure (9) relates to the solid composition according to any one of the disclosures (1) to (8),
wherein the solid composition has a dissipation factor at 25° C. and 10 GHz of 0.003 or lower.

The disclosure (10) relates to the solid composition according to any one of the disclosures (1) to (9), which is in the form of film or sheet.

The disclosure (11) relates to the solid composition according to any one of the disclosures (1) to (10), which is used for an insulating material of a circuit board.

The disclosure (12) relates to the solid composition according to the disclosure (11), wherein the insulating material of the circuit board includes a low dielectric material.

The disclosure (13) relates to a circuit board (hereinafter, also referred to as the circuit board of the disclosure) including:
the solid composition according to any one of the disclosures (1) to (12); and
a conductive layer.

The disclosure (14) relates to the circuit board according to the disclosure (13),
wherein the conductive layer includes metal.

The disclosure (15) relates to the circuit board according to the disclosure (14),
wherein the metal has a surface having a surface roughness Rz of 2.0 μm or lower on a side facing the solid composition.

The disclosure (16) relates to the circuit board according to the disclosure (14) or (15),
wherein the metal includes copper.

The disclosure (17) relates to the circuit board according to any one of the disclosures (13) to (16), which is a printed circuit board, a multilayer circuit board, or a high frequency board.

The disclosure (18) relates to a method for producing the solid composition according to any one of the disclosures (1) to (12) (hereinafter, also referred to as “the production method of the disclosure”), the method including:
melt-kneading the perfluorinated fluororesin and the anisotropic filler to provide the solid composition.

### Examples

The disclosure is described in more detail below with reference to examples, but is not limited to these examples.

The materials used in the examples are as follows. (Perfluorinated fluororesin)
PFA 1 (TFE/PAVE (% by mass): 97.9/2.1, amount of fluorine-containing monomer: 100 mol %, melting point: 304° C., MFR: 29 g/10 min, relative permittivity (25° C., 10 GHz): 2.1, dissipation factor (25° C., 10 GHz): 0.0003)
PFA 2 (TFE/PAVE (% by mass): 97.9/2.1, amount of fluorine-containing monomer: 100 mol %, melting point: 303° C., MFR: 29 g/10 min, relative permittivity (25° C., 10 GHz): 2.0, dissipation factor (25° C., 10 GHz): 0.001)
FEP (TFE/HFP/PAVE (% by mass): 87.5/11.5/1.0, amount of fluorine-containing monomer: 100 mol %, melting point: 255° C., MFR: 24 g/10 min, relative permittivity (25° C., 10 GHz): 2.1, dissipation factor (25° C., 10 GHz): 0.0008) (Filler)
Talc 1 (average particle size: 7 μm, aspect ratio: 45 to 50, Mohs hardness (original Mohs hardness): 1, surface treatment: treatment with fluorosilane (silane coupling agent containing fluorine-containing group))
Talc 2 (average particle size: 7 μm, aspect ratio: 30, Mohs hardness (original Mohs hardness): 1, surface treatment: treatment with fluorosilane (silane coupling agent containing fluorine-containing group))
Talc 3 (average particle size: 7 μm, aspect ratio: 30, Mohs hardness (original Mohs hardness): 1, surface treatment: treatment with aminosilane (amino group-containing silane coupling agent))
Talc 4 (average particle size: 7 μm, aspect ratio: 30, Mohs hardness (original Mohs hardness): 1, surface treatment: treatment with vinylsilane (vinyl group-containing silane coupling agent))
Talc 5 (average particle size: 5 μm, aspect ratio: 30, Mohs hardness (original Mohs hardness): 1, surface treatment: treatment with fluorosilane (silane coupling agent containing fluorine-containing group))
Talc 6 (average particle size: 7 μm, aspect ratio: 45 to 50, Mohs hardness (original Mohs hardness): 1, no surface treatment)
Zinc oxide (average particle size: 0.035 μm, no surface treatment, having ultraviolet absorbency (absorbance of light at a wavelength of 355 nm is 0.1 or more))

The number of unstable end groups in the perfluorinated fluororesin is shown in the following table. The number was measured by the same method as described in examples described below using a film-shaped sample cut out of a pellet or sheet formed from the perfluorinated fluororesin.

TABLE 1

| | | | CF₂H | | Unstable end group other than CF₂H | | |
|---|---|---|---|---|---|---|---|
| | | | Number/per 10⁶ | | | Number/per 10⁶ | |
| | | | carbon atoms | | | carbon atoms | |
| [symbol] | Composition/wt % | MFR | Pellet | Sheet | Kind | Pellet | Sheet |
| PFA1 | TFE/PAVE = 97.9/2.1 | 29 | 0 | 0 | COF, COOH, COOCH₃, | 0 | 29 |
| | | | | | CONH₂, CH₂OH | | |
| PFA2 | TFE/PAVE = 97.9/2.1 | 29 | 138 | 159 | COF, COOH, COOCH₃, CH₂OH | 285 | 300-400 |
| FEP | TFE/HFP/PAVE = 87.5/11.5/1 | 24 | 483 | 531 | COF, COOH | 34 | 40-80 |

### Examples and Comparative Examples

<Method for Producing Pellets in Examples Other than Example 2>

A perfluorinated fluororesin and a filler were melt-kneaded at the ratio (% by mass) shown in the table below at 360° C. using a twin screw kneader and then cooled in a water bath, whereby a solid composition was obtained. The solid composition (strand) was cut into pellets.

### <Method for Producing Pellets in Example 2>

A perfluorinated fluororesin and a filler were melt-kneaded (duration: 600 seconds, temperature: 350° C.) at the ratio (% by mass) shown in the table below using a Labo Plastomill mixer and then naturally cooled, whereby a solid composition was obtained. The obtained solid composition was pulverized into pellets.

The pellets obtained above were press-molded at 350° C. to obtain a sheet with a thickness of 100 μm. In Comparative Example 4, a sheet was not formed due to low flowability.

In Example 10, the sheet obtained in Example 1 and copper foil (electrolytic copper, thickness: 18 μm, surface roughness Rz on a side to be joined to the sheet: 1.4 μm) were stacked and pressed at a heating temperature of 320° C. and a pressure of 15 kN for five minutes. Thus, a joined article including the sheet joined to one side of the copper foil was obtained.

### (Stability in Taking Up Strand)

The stability in taking up a strand during forming the pellets was evaluated by the following criteria.
Excellent: Stable
Good: Sometimes break
Poor: Impossible to take up strand

### (Sheet Moldability)

The moldability in forming the sheet was evaluated by the following criteria.
Excellent: No bubble trapped
Good: Partially no bubble trapped

### (Number of Voids (Image Analysis by Laser Microscopy))

The number of voids having a width of 30 μm or greater per 1 mm² area was evaluated.

The pellet was cut with a razor and the cross section was observed with a laser microscope. For the number of voids, the number of voids per 0.069 mm² area (length 0.23 mm, width 0.3 mm) in an image obtained at a magnification of 50 was counted, and the number was then converted into the number of voids per 1 mm² area.

### (Reduction Percentage in Linear Expansion Coefficient (CTE))

The linear expansion coefficient of the sheet was determined by a TMA measurement in the mode described below using TMA-7100 (available from Hitachi High-Tech Science Corp.).

The same measurement was performed on the perfluorinated fluororesin. The reduction percentage relative to the linear expansion coefficient (linear expansion coefficient before adding filler) of the resin alone was calculated and evaluated by the criteria described below.

### [Tensile Mode Measurement]

A sample piece was prepared by cutting an extruded film into a size with a length of 20 mm, a width of 4 mm, and a thickness of 25 μm. The sample piece was pulled at a load of 49 mN under a temperature-increasing rate of 2° C./min. The linear expansion coefficient was determined from the amount of displacement of the sample between 20° C. to 200° C.

### [Equation to Calculate Reduction Percentage]

$$( Reduction percentage / \% ) = ( B 1 - B 2 ) \times 100 / B 1$$

B1: Linear expansion coefficient/ppm/° C. before adding filler
B2: Linear expansion coefficient/ppm/° C. after adding filler

### [Criteria]

Excellent: 50% or higher
Good: Lower than 50% and 25% or higher
Poor: Lower than 25%

### (Relative Permittivity (Dk), Dissipation Factor (Df))

The Dk and Df of the sheet at 25° C. and 10 GHz were measured using a split cylinder permittivity/dissipation factor measurement apparatus (available from EM lab) and evaluated by the following criteria.

### [Relative Permittivity Criteria]

Excellent: Less than 5

### [Dissipation Factor Criteria]

Excellent: Less than 0.0012
Good: 0.0012 or more and less than 0.003

### (Peeling Test)

A peeling test (90° peeling test) was performed in accordance with the method in JIS C 6481-1996. About 1 cm portion of the resin at an edge of the joined article in Example 10 was peeled. The peeled portion was gripped with the chuck of a tester. The peeling strength (unit: N/cm) was measured at a tensile speed (moving speed) of 50 mm/min and evaluated by the following criteria.
Excellent: 10 N/cm or more

TABLE 2

| | | Physical properties of filler | | | | | | | | |
|---|---|---|---|---|---|---|---|---|---|---|
| | | | | Surace- | | | | | | |
| | | Particle | Aspect | treating | Example | | | | | |
| | | size/um | ratio | agent | 1 | 2 | 3 | 4 | 5 | 6 |
| Composition | PFA 1 | — | — | — | 80 | 70 | 80 | 80 | 80 | 80 |
| (% by mass) | PFA 2 | — | — | — | | | | | | |
| | FEP | — | — | — | | | | | | |
| | Talc 1 | 7 | 45-50 | Fluorosilane | 20 | 30 | | | | |
| | Talc 2 | 7 | 30 | Fluorosilane | | | 20 | | | |
| | Talc 3 | 7 | 30 | Aminosilane | | | | 20 | | |
| | Talc 4 | 7 | 30 | Vinylsilane | | | | | 20 | |
| | Talc 5 | 5 | 30 | Fluorosilane | | | | | | 20 |
| | Talc 6 | 7 | 45-50 | No surface | | | | | | |
| | | | | treatment | | | | | | |
| | Zinc oxide | 0.035 | — | With surface | | | | | | |
| | | | | treatment | | | | | | |
| Cu foil with surface | | — | — | — | — | — | — | — | — | — |
| roughness Rz of 1.4 um | | | | | | | | | | |
| Moldability | Stability in | — | — | — | Excellent | Excellent | Excellent | Excellent | Excellent | Excellent |
| | pulling | | | | | | | | | |
| | out strand | | | | | | | | | |
| | Sheet | — | — | — | Excellent | Excellent | Excellent | Excellent | Excellent | Excellent |
| | moldability | | | | | | | | | |
| | Number of | — | — | — | 0 | 14 | 0 | 0 | 0 | 0 |
| | voids/per | | | | | | | | | |
| | 1 mm⁻² | | | | | | | | | |
| CTE | Evaluation | — | — | — | Good | Excellent | Good | Good | Good | Good |
| reduction | Measured | — | — | — | 46% | 60% | 48% | 44% | 43% | 47% |
| percentage | value | | | | | | | | | |
| Relative | Evaluation | — | — | — | Excellent | Excellent | Excellent | Excellent | Excellent | Excellent |
| permittivity | Measured | — | — | — | 2.6 | 2.9 | 2.5 | 2.6 | 2.5 | 2.6 |
| | value | | | | | | | | | |
| Dissipation | Evaluation | — | — | — | Excellent | Excellent | Excellent | Excellent | Excellent | Excellent |
| factor | Measured | — | — | — | 0.000812 | 0.0011 | 0.0008 | 0.0008 | 0.0009 | 0.0009 |
| | value | | | | | | | | | |

| Peeling test | — | — | — | — | — | — | — | — | — |
|---|---|---|---|---|---|---|---|---|---|
| | | Example | | | | Comparative Example | | | |
| | | 7 | 8 | 9 | 10 | 1 | 2 | 3 | 4 |
| Composition | PFA 1 | | | 79.5 | 80 | 100 | 80 | 94 | 35 |
| (% by mass) | PFA 2 | 80 | | | | | | | |
| | FEP | | 80 | | | | | | |
| | Talc 1 | 20 | 20 | 20 | 20 | | | | |
| | Talc 2 | | | | | | | | |
| | Talc 3 | | | | | | | | |
| | Talc 4 | | | | | | | | |
| | Talc 5 | | | | | | | | |
| | Talc 6 | | | | | | 20 | 6 | 65 |
| | Zinc oxide | | | | | 0.5 | | | |
| Cu foil with surface | | — | — | — | Present | — | — | — | — |
| roughness Rz of 1.4 um | | | | | | | | | |
| Moldability | Stability in | Excellent | Excellent | Excellent | Excellent | Excellent | Good | Good | Poor |
| | pulling | | | | | | | | |
| | out strand | | | | | | | | |
| | Sheet | Excellent | Excellent | Excellent | Excellent | Excellent | Good | Good | — |
| | moldability | | | | | | | | |
| | Number of | 0 | 14 | 0 | 0 | 0 | 71 | 0 | — |
| | voids/per | | | | | | | | |
| | 1 mm⁻² | | | | | | | | |
| CTE reduction | Evaluation | Good | Good | Good | Good | Poor | Good | Poor | — |
| percentage | Measured | 48% | 48% | 45% | 46% | 0% | 47% | 20% | — |
| | value | | | | | | | | |
| Relative | Evaluation | Excellent | Excellent | Excellent | Excellent | Excellent | Excellent | Excellent | — |
| permittivity | Measured | 2.5 | 2.5 | 2.6 | 2.6 | 2.1 | 2.7 | 2.1 | — |
| | value | | | | | | | | |
| Dissipation | Evaluation | Good | Good | Excellent | Excellent | Excellent | Excellent | Excellent | — |
| factor | Measured | 0.0014 | 0.0013 | 0.001 | 0.0008 | 0.0003 | 0.0008 | 0.0004 | — |
| | value | | | | | | | | |

| | | | | | | | |
|---|---|---|---|---|---|---|---|
| Peeling test | — | — | — | Excellent | — | — | — |

1. A solid composition comprising:
a perfluorinated fluororesin; and
an anisotropic filler surface-treated with a silane coupling agent;
wherein the perfluorinated fluororesin has a melting point of 240° C. to 340° C.;
wherein the amount of the perfluorinated fluororesin relative to the solid composition is 40 to 90% by mass; and
wherein the solid composition is a film or sheet having a thickness of 50 μm or more.

2. The solid composition according to claim 1,
wherein the anisotropic filler includes at least one of talc or boron nitride.

3. The solid composition according to claim 1,
wherein the anisotropic filler has a Mohs hardness of 4 or lower.

4. The solid composition according to claim 1,
wherein the silane coupling agent contains at least one selected from the group consisting of a fluorine-containing group, an amino group, a vinyl group, and an epoxy group.

5. The solid composition according to claim 1,
wherein the perfluorinated fluororesin contains less than 50 unstable end groups per 1×106 carbon atoms,
the unstable end groups include at least one selected from the group consisting of —CF₂H, —COF, —COOH, —COOCH₃, —CONH₂, and —CH₂OH present at a main chain end of the perfluorinated fluororesin.

6. The solid composition according to claim 1,
wherein the perfluorinated fluororesin includes at least one selected from the group consisting of polytetrafluoroethylene, a tetrafluoroethylene/perfluoro(alkyl vinyl ether) copolymer, and a tetrafluoroethylene/hexafluoropropylene copolymer.

7. The solid composition according to claim 1,
wherein the solid composition has 30 or less voids having a width of 30 μm or greater per 1 mm² area in image analysis by laser microscopy.

8. The solid composition according to claim 1,
wherein the solid composition has a reduction percentage in linear expansion coefficient at 20° C. to 200° C. of 25% or higher relative to a linear expansion coefficient at 20° C. to 200° C. of the perfluorinated fluororesin.

9. The solid composition according to claim 1,
wherein the solid composition has a dissipation factor at 25° C. and 10 GHz of 0.003 or lower.

10. The solid composition according to claim 1, which is used for an insulating material of a circuit board.

11. The solid composition according to claim 10,
wherein the insulating material of the circuit board includes a low dielectric material.

12. A circuit board comprising:
the solid composition according to claim 1; and
a conductive layer.

13. The circuit board according to claim 12,
wherein the conductive layer includes metal.

14. The circuit board according to claim 13,
wherein the metal has a surface having a surface roughness Rz of 2.0 μm or lower on a side facing the solid composition.

15. The circuit board according to claim 13,
wherein the metal includes copper.

16. The circuit board according to claim 12, which is a printed circuit board, a multilayer circuit board, or a high frequency board.

17. A method for producing the solid composition according to claim 1, the method comprising:
melt-kneading the perfluorinated fluororesin and the anisotropic filler to provide the solid composition.
